(19) United States
(12) Patent Application Publication
(10) Pub. No.: US 2013/0235296 A1
(43) Pub. Date: Sep. 12, 2013

(54) Backlight Module and LCD Device

(71) Applicant: Yanxue Zhang, Shenzhen (CN)

(72) Inventor: Yanxue Zhang, Shenzhen (CN)

(21) Appl. No.: 13/501,309

(22) PCT Filed: Mar. 26, 2012
(86) PCT No.: PCT/CN2012/073027

§ 371 Date: Apr. 11, 2012

(30) Foreign Application Priority Data
Mar. 6, 2012 (CN) 201210056958.3

(51) Int. Cl. G02F 1/1333; H05K 7/18

(52) U.S. Cl. 349/58; 361/813

(57) ABSTRACT

The invention relates to the field of LCDs, and more particularly to a backlight module and an LCD device. The backlight module includes a ferromagnetic metal component; the metal component is provided with a screw hole, and a screw matched with the screw hole is a magnetic tapping screw. The metal component of the backlight module of the invention is made of ferromagnetic material and can be attracted by a magnetic ferromagnet, the screw hole of the metal component can be simply tapped after accomplishing the drilling process without being tapped to the qualified size and even without being tapped, and then the magnetic tapping screw is matched with the screw hole; when the tapping screw drills, the small iron debris produced in the screw hole of the metal component can be attracted by the magnetic tapping screw, and cannot drop into the cavity of the backlight module, thereby avoiding damage to the optical film, and preferably ensuring the product quality; because the tapping standard of the screw hole of the metal component is reduced, or the tapping process is omitted, the cost of the metal component is reduced.

### TECHNICAL FIELD

The invention relates to the field of liquid crystal displays (LCDs), and more particularly to a backlight module and an LCD device comprising the backlight module.

### BACKGROUND

All conventional backlight modules in mass production employ a large number of screws to lock all the components. For plastic components, only screw holes of appropriate aperture are required to be directly drilled by tapping screws in general. However, for metal components, because some small debris may be produced in the screw holes of the metal components when the tapping screws drill, the debris may drop inside the backlight modules, thereby resulting in scratches of optical films of the backlight modules, and affecting the product quality. Thus, the current general mode is that: the screw holes of the metal components are tapped, and the metal components are locked by ordinary mechanical thread screws. Therefore, debris cannot be produced. However, the tapping process of the metal components is relatively complicated, and the tapping cost is high. Furthermore, the display area of backlight modules becomes larger, the number of employed screws becomes more, the number of screw holes which require pre-tapping becomes more, and the manufacture cost of the metal components also becomes higher.

### SUMMARY

In view of the above-described problems, the aim of the present invention is to provide a backlight module of low cost and an LCD device.

A first technical scheme of the invention is that: a backlight module comprises a front frame, an optical film, and a backplane; the optical film is arranged between the front frame and the backplane, and the front frame is connected with the backplane by a tapping screw; the front frame is a ferromagnetic metal component, the metal component is provided with a screw hole, a screw matched with the screw hole is a magnetic tapping screw, the tapping screw is made of permanent magnet material, the screw hole is an untapped screw hole, and the metal component is an iron metal component.

A second technical scheme of the invention is that: a backlight module comprises a ferromagnetic metal component; the metal component is provided with a screw hole, and a screw matched with the screw hole is a magnetic tapping screw.

Preferably, the screw hole is an untapped screw hole. The tapping process is completely omitted, and then the cost is reduced to a maximum extent.

Preferably, the metal component is an iron metal component because iron material is frequently used and has low cost.

Preferably, the tapping screw is made of permanent magnet material, thereby ensuring that the tapping screw cannot reduce magnetism to release the attracted debris into the inside of the backlight module.

Preferably, the backlight module comprises a front frame, an optical film, and a backplane; the optical film is arranged between the front frame and the backplane, the front frame is connected with the backplane by a tapping screw, and the metal component is the front frame.

A third technical scheme of the invention is that: an LCD device comprises a backlight module; the backlight module comprises a ferromagnetic metal component, the metal component is provided with an untapped screw hole, and a screw matched with the screw hole is a magnetic tapping screw.

Preferably, the screw hole is an untapped screw hole.

Preferably, the metal component is an iron metal component.

Preferably, the tapping screw is made of permanent magnet material.

Preferably, the backlight module comprises a front frame, an optical film, and a backplane; the optical film is arranged between the front frame and the backplane, the front frame is connected with the backplane by a tapping screw, and the metal component is the front frame.

Advantages of the invention are summarized below: the metal component of the backlight module of the LCD device of the invention is made of ferromagnetic material and can be attracted by a magnetic ferromagnet, the screw hole of the metal component can be simply tapped after accomplishing the drilling process without being tapped to the qualified size and even without being tapped, and then the magnetic tapping screw is matched with the screw hole; when the tapping screw drills, the small iron debris produced in the screw hole of the metal component can be attracted by the magnetic tapping screw and cannot drop into the cavity of the backlight module, thereby avoiding damage to the optical film, and preferably ensuring the product quality; because the tapping standard of the screw hole of the metal component is reduced, or the tapping process is omitted, the cost of the metal component is reduced.

### BRIEF DESCRIPTION OF FIGURES

FIG. 1 is a structure diagram of an example of a backlight module of the invention.

Legends: 1. front frame; 11. screw hole; 2. backplane; 3. tapping screw.

### DETAILED DESCRIPTION

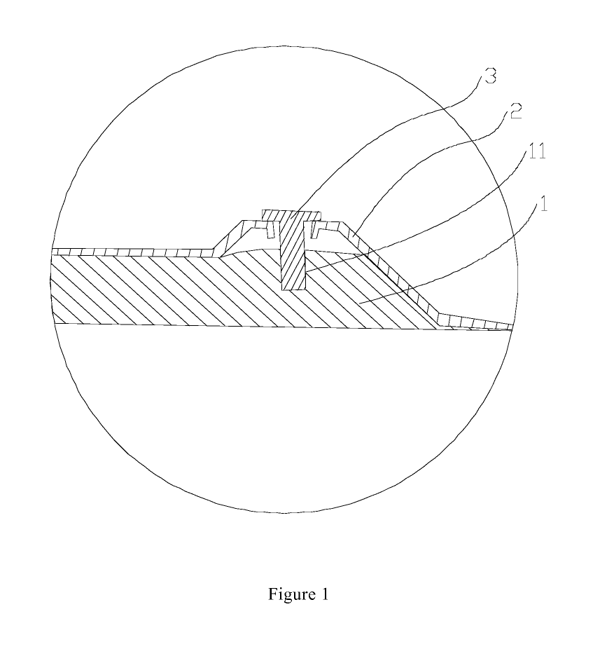

The invention provides an LCD device comprising a backlight module. FIG. 1 shows an example of the backlight module. The backlight module comprises a front frame 1, an optical film (not shown in the FIGURE), and a backplane 2; the optical film is arranged between the front frame 1 and the backplane 2, and the front frame 1 is connected with the backplane 2 by a tapping screw 3; the front frame 1 is a ferromagnetic metal component, the front frame 1 is provided with a screw hole 11 which is simply tapped or is not tapped totally, and a screw matched with the screw hole 11 is a magnetic tapping screw 3.

The front frame 1 of the backlight module of the LCD device of the invention is made of ferromagnetic material and can be attracted by a magnetic ferromagnet, the screw hole 11 of the front frame 1 can be simply tapped after accomplishing the drilling process without being tapped into qualified size and even without being tapped, and then the magnetic tapping screw 3 is matched the screw hole 11; when the tapping screw 3 drills, small iron debris produced in the screw hole 11 of the front frame 1 can be attracted by the magnetic tapping screw 3 and cannot drop into the cavity of the backlight module, thereby avoiding damage to the optical film, and preferably ensuring the product quality. Because the tapping standard of the screw hole of the front frame 1 is reduced, or the tapping process is omitted, the cost of the front frame 1 is reduced.

In the example, the front frame 1 is preferably made of iron material because the iron material is frequently used and has low cost; the tapping screw is preferably made of permanent magnet material, thereby ensuring that the tapping screw 3 cannot reduce magnetism to release the attracted debris into the inside of the backlight module.

Optionally, the aforementioned ferromagnetic metal component locked by the screw is not limited to the front frame; it can also be other components such as backplane, etc.

The invention is described in detail in accordance with the above contents with the specific preferred examples. However, this invention is not limited to the specific examples. For the ordinary technical personnel of the technical field of the invention, on the premise of keeping the conception of the present invention, the technical personnel can also make simple deductions or replacements, and all of which should be considered to belong to the protection scope of the invention.

We claim:

1. A backlight module, comprising a front frame, an optical film, and a backplane; wherein said optical film is arranged between said front frame and said backplane, and said front frame is connected with said backplane by a tapping screw; said front frame is a ferromagnetic metal component, said metal component is provided with a screw hole, a screw matched with said screw hole is a magnetic tapping screw, said tapping screw is made of permanent magnet material, said screw hole is an untapped screw hole, and said metal component is an iron metal component.

2. A backlight module, comprising a ferromagnetic metal component; wherein said metal component is provided with a screw hole, and a screw matched with said screw hole is a magnetic tapping screw.

3. The backlight module of claim 2, wherein said screw hole is an untapped screw hole.

4. The backlight module of claim 3, wherein said metal component is an iron metal component.

5. The backlight module of claim 3, wherein said tapping screw is made of permanent magnet material.

6. The backlight module of claim 3, wherein said backlight module comprises a front frame, an optical film, and a backplane; said optical film is arranged between said front frame and said backplane, said front frame is connected with said backplane by a tapping screw, and said metal component is said front frame.

7. An LCD device, comprising: a backlight module; said backlight module comprises a ferromagnetic metal component, said metal component is provided with an untapped screw hole, and a screw matched with said screw hole is a magnetic tapping screw.

8. The LCD device of claim 7, wherein said screw hole is an untapped screw hole.

9. The LCD device of claim 8, wherein said metal component is an iron metal component.

10. The LCD device of claim 8, wherein said tapping screw is made of permanent magnet material.

11. The LCD device of claim 8, wherein said backlight module comprises a front frame, an optical film, and a backplane; said optical film is arranged between said front frame and said backplane, said front frame is connected with said backplane by a tapping screw, and said metal component is said front frame.
